(19) United States
(12) Patent Application Publication
(10) Pub. No.: US 2012/0033366 A1
(43) Pub. Date: Feb. 9, 2012

(54) Hands-Free Carrier For Portable Electronic Media Devices

(76) Inventor: Noble Milton, Newark, NJ (US)

(21) Appl. No.: 13/205,192

(22) Filed: Aug. 8, 2011

Related U.S. Application Data
(60) Provisional application No. 61/371,206, filed on Aug. 6, 2010.

(51) Int. Cl. H05K 7/00

(52) U.S. Cl. 361/679.01

(57) ABSTRACT

A hands-free carrier for a portable electronic media player device is described. The carrier has a headset, an extension boom, and a holder assembly for the device. The headset is attached to one end of the extension boom and the holder assembly is attached to the other end of the extension boom via a connection assembly. The hands-free carrier supports the electronic media player at an easy to read angle.

### CLAIM OF PRIORITY

This application claims the priority of U.S. Ser. No. 61/371,206 filed on Aug. 6, 2010, the contents of which are fully incorporated herein by reference.

### FIELD OF INVENTION

The present invention relates to a hands-free carrier having a headset, extension boom and suitable holder assembly for holding portable electronic media devices. The present invention also relates to a hands-free carrier for viewing and listening to portable media devices, and more particularly to headgear especially adapted to carry a portable media device, while allowing a user to view and manipulate the media device in the field of vision.

### BACKGROUND OF THE INVENTION

Portable media devices are well known and take many forms. These include AM and FM radios, audio tape players, and digital media players such as iPod and MP3 players.

In recent years portable electronic media devices have become small, light and powerful. One factor contributing to this phenomenon is in the manufacturer's ability to fabricate various components of these devices in smaller and smaller sizes while in most cases increasing the power and or operating speed of such components. Because of their decreased size and weight, the portable electronic media devices are easily transportable and thus they may be carried by people when performing physical activities such as walking, running, cycling, stair climbing, etc. In some cases, the devices are held in the user's hand, while in other cases the devices are carried in a pocket or worn by the user via attaching them to a belt or by strapping them to the arm thus freeing their hands.

Several authors have suggested adapting headgear, such as caps, visors or headbands to carry speakers or to function with audio devices connected to ear buds, thereby shortening or eliminating the electrical cords connecting the ear buds to the audio device. Some of these prior art suggestions are described below in a listing which is exemplary, but not necessarily all-inclusive.

U.S. Pat. No. 4,864,619 to Spates shows headphone speakers built into a soft resilient headband connected via a cord leading from the back of the headband to a stereo jack.

U.S. Pat. No. 5,438,698 to Burton et al. describe a wearable audio device removably attached to an enclosure that, in turn, is removably attached to the back of a headband. The enclosure contains an electrical connecting cord (looped back and forth to serve as a radio antenna) extending from a plug-in jack to a pair of ear buds.

U.S. Pat. No. 5,881,160 to Sheppard discloses a cap with a support bracket positioned inside the cap holding a tape player inside the crown electrically connected on opposite sides to speakers disposed in small ear pieces hanging from the lower edge of the cap. The settings and adjustments of the tape player must be made before the cap is put on and the speakers put in place.

U.S. Pat. No. 7,044,615 to Gesten discloses a billed cap with an audio device built into the bill. Speakers, controls and a visual display are on the underside of the bill.

U.S. Patent Publication No. 2007/0226876 to Foust et al discloses a cap with pockets for carrying an MP3 player and the associated wires. One of the pockets holds the audio device and a separate pocket holds the wires.

MP3 players are increasingly popular devices that are used to play music. One disadvantage in all of the foregoing devices is the inability to see and manipulate the controls of the media device while wearing the hands-free carrier.

Despite all of this, however, the need still remains for a versatile carrier for electronic media devices (e.g., MEDIA players) so that one can easily utilize the full breadth of the capabilities of the electronic media devices while being hands-free and being accessible to the user. The need also exists for such units that are stable, light-weight, have rigid but adjustable positioning elements, and/or are portable so that they can be used. Finally, the need also exists for such carriers that are superior in comfort, convenience, but without sacrificing portability, stability, versatility, and/or aesthetics.

### SUMMARY OF THE INVENTION

An embodiment of the present invention discloses a hands-free carrier for a portable electronic media player device, said carrier having a headset; an extension boom having a proximal end and a distal end; the extension boom being attached to the headset; the headset being attached to the proximal end of the extension boom; an holder assembly suitable for holding a portable electronic media player device being attached to the distal end of the extension boom via a connection assembly.

The invention concerns a holder assembly to hold an electronic device (e.g., MP3 player) during use.

Accordingly, one object of the present invention is to provide hands-free carrier especially adapted for connecting, adjusting, docking and listening to a portable media device.

Another object of the invention is to provide hands-free carrier especially adapted to carry a media device and to connect it for listening and manipulating the controls of the media device in the field of vision of a user while wearing the hands-free carrier.

In an embodiment of the present invention, a hands-free carrier for a portable media player includes a holder assembly that holds the media player at an angle that allows a display of the media player to be easily viewed. The holder assembly may include at least one cable slot such that a cable attached to the media player can extend outward from the holder. The carrier and holder are constructed from a soft material or plastic such that the holder does not scratch the digital media player.

The holder assembly has a digital media player receiving section that is designed to support the digital media player such that a display of the digital media player is visible to the user. The holder assembly has an enclosure suitable for holding a portable electronic media player portion.

The invention relates, in another embodiment, to a hands-free carrier for an electronic device that includes an adjustable extension boom, a headset for placement around a user's head, and a holder assembly supported by an adjustable extension boom such that the electronic device holder assembly connects to the headband via an adjustable extension boom. The electronic device holder assembly includes a connector for anchoring an electronic device to an adjustable extension boom.

The invention relates, in another embodiment, to a hands-free carrier. The hands-free carrier includes an extension boom attached to a proximal end of a headband which is worn around the head of the user. The hands-free carrier also includes a holder assembly physically carried on the extension boom and configured to releasably engage a portable media player. The holder assembly intimately and rigidly mates with the portable media player so that the portable media player is an extension boom of the holder assembly when engaged thereto.

In another aspect, the invention concerns a holder assembly for an electronic media device comprising a cavity for receiving and releasably holding the electronic media device, the cavity being defined by at least a bottom wall and a sidewall, the sidewall fitting around the electronic device to help retain the electronic device within the cavity.

Other features and advantages are described below and still others will be apparent to those skilled in the art.

### BRIEF DESCRIPTION OF THE DRAWINGS

The invention will be better understood by reference to the following description, taken in connection with the accompanying drawings, in which:

FIG. 1 is a perspective view of a hands-free carrier 10 for a portable electronic media player device having a headset 20, the headset 20 having a set of speakers 30, an extension boom 40 having a proximal end 50 and a distal end 60, the extension boom 40 being attached to the headset 20, the headset 20 being attached to the proximal end 50 of the extension boom 40; an holder assembly 70 suitable for holding a portable electronic media player device being attached to the distal end 60 of the extension boom 40 via a connection assembly 80.

FIG. 2 is a perspective view of a hands-free carrier 10 for a portable electronic media player device having a headset 20, an extension boom 40 having a proximal end 50 and a distal end 60, the extension boom 40 being attached to the headset 20, the headset 20 being attached to the proximal end 50 of the extension boom 40; an holder assembly 70 suitable for holding a portable electronic media player device being attached to the distal end 60 of the extension boom 40 via a connection assembly 80.

FIG. 3 is a perspective view of a hands-free carrier 10 for a portable electronic media player device having a headband 90, an extension boom 40 having a proximal end 50 and a distal end 60, the extension boom 40 being attached to the headset 20, the headset 20 being attached to the proximal end 50 of the extension boom 40; an holder assembly 70 suitable for holding a portable electronic media player device being attached to the distal end of the extension boom 40 via a connection assembly 80.

FIG. 4 is a perspective view of a hands-free carrier 10 for a portable electronic media player device having a headset 20, the headset 20 having a set of speakers 30, an extension boom 40 with a slidably adjustable mechanism 100, the extension boom having a proximal end 50 and a distal end 60, the extension boom 40 being attached to the headset 20, the headset 20 being attached to the proximal end 50 of the extension boom 40; an holder assembly 70 suitable for holding a portable electronic media player device being attached to the distal end 60 of the extension boom 40 via a pivotable connection assembly 80.

FIG. 5 is a perspective view of a hands-free carrier 10 for a portable electronic media player device having a cap with a visor, an extension boom 40 having a proximal end 50 and a distal end 60, the extension boom 40 being attached to the visor of the cap, an holder assembly 70 suitable for holding a portable electronic media player device being attached to the distal end of the extension boom 40 via a connection assembly 80.

FIG. 6 is a perspective view from the back of a user wearing the hands-free carrier 10 depicted in FIG. 1.

These drawings are for illustrative purposes only and should not be used to unduly limit the scope of the invention.

### DETAILED DESCRIPTION OF THE INVENTION

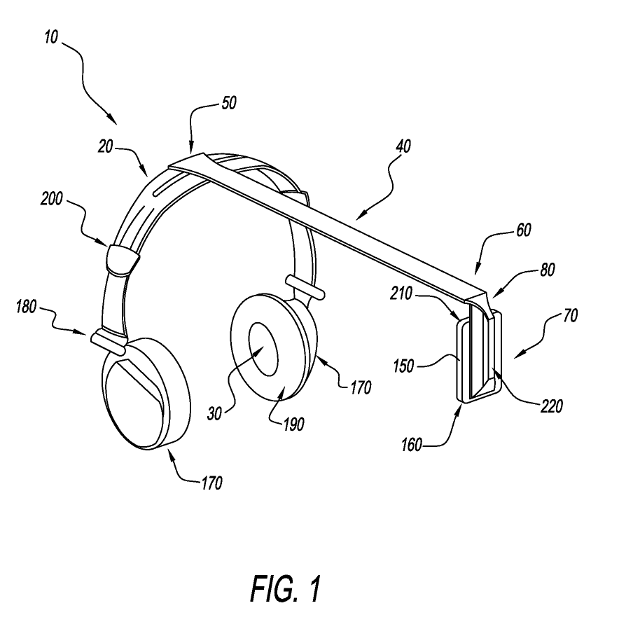

Embodiments of the invention are discussed below with reference to FIGS. 1-6. However, those skilled in the art will readily appreciate that the detailed description given herein with respect to these figures is for explanatory purposes as the invention extends beyond these limited embodiments.

The hands-free carrier of the present invention holds a portable media player, including but not limited to the iPod™ media player, tightly in position. The hands-free carrier is easily adjustable (both electronically and mechanically), is sleek and aesthetically appealing, and allows easy repositioning of the holder with respect to a headset to accommodate a wide range of users.

FIG. 1 is a perspective view of an embodiment of a hands-free carrier 10 for a portable electronic media device having a headset 20, the headset 20 having a set of speakers 30, an extension boom 40 having a proximal end 50 and a distal end 60, the extension boom 40 being attached to the headset 20, the headset 20 being attached to the proximal end 50 of the extension boom 40; an holder assembly 70 being suitable for holding a portable electronic media player device being attached to the distal end 60 of the extension boom 40 via a connection assembly 80.

In one embodiment of the present invention, the connection assembly 80 is a pivot hinge and the connection assembly is rotatable. Thus, the user can wear the hands-free carrier with the electronic device facing him, or he may rotate the connection assembly such that the electronic device is facing to the side or away from him. This may be desirable, for instance, when another person wishes to view the device while the user is wearing it, or when the user doesn't want to see what's currently showing on the device, for instance, a particularly violent scene in a movie.

It is contemplated that the holder be made of a relatively soft material such as plastic that will not scratch or harm the exterior of a portable media player inserted into the holder assembly. For example, although plastic (such as but not limited to, acrylonitrile-butadiene-styrene, polyacrylate, phenolformaldehyde resin, polyethylene, polypropylene, polyphenylene oxide, polycarbonate, polyamide (e.g., nylon), polyacetal, polyurethane, polystyrene, polyvinyl chloride, reinforced plastics, ureaformaldehyde resin, etc.) may be used for the various parts of different embodiments of this invention, some or all of those parts may also be made of other materials, such as but not limited to, metal or polymers.

The holder assembly 70 holds the media player at an easy to view angle, most preferably 90 degrees or less, that allows the media player's display to be read and the media player's function keys to accessed and manipulated with the media player is resting in the holder assembly 70. The holder assembly 70 is attached to the distal end 60 of the extension boom 40 via a connection assembly 80. The connection assembly 80 may be fixed in permanent position or it may be adjustable or rotatable. As shown in FIGS. 1-6, the holder assembly 70 is formed with sidewalls 150, bottom wall 160, top wall 210, and back wall 220 which are adapted to receive desired media players of different sizes and hold them at the desired angle.

The holder assembly 70 may have a cable attachment cavity (not shown) for a docking connector to attach to a media player placed in the holder assembly 70. It is contemplated that a pair of cable slots (not shown) may also be provided in the holder assembly 70 to allow a cable to easily extend from the docking connector attached to an media player placed in the holder assembly 70.

The invention pertains to improved approaches for carrying or wearing portable electronic media devices. One aspect of the invention relates to making the portable electronic media devices easier to wear while remaining in the user's field of vision. For example, by utilizing extension boom 40, the portable electronic device can be supported by the user's head. As a result, the device is mobile, easy to transport, easy to view and manipulate while remaining in the user's field of vision.

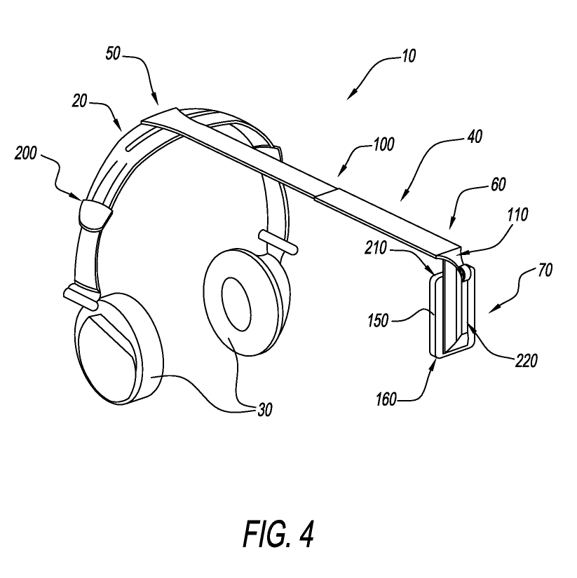

As seen in FIG. 1, an embodiment of the hands-free carrier 10 for a portable electronic media player device, has a headset 20; an extension boom 40 having a promixal end 50 and a distal end 60; the extension boom 40 being attached to the headset 20; the headset 20 being attached to the proximal end 50 of the extension boom 40; holder assembly 70 suitable for holding a portable electronic media player device being attached to the distal end 50 of the extension boom 40 via a connection assembly 80, in accordance with one embodiment of the present invention. In one embodiment of the present invention, as shown in FIG. 4, the connection assembly 80 is a pivot hinge 110.

The headset 20 is formed for placement around a person's head. The extension boom 40 may have a fixed length or it may be adjustable to accommodate different user preferences or usages.

In one embodiment, as seen in FIG. 1, a pair of earcups 170 having a set of speakers 30 inserted therein, are connected to an adjustable headset 20. It will be understood that various embodiments of the present invention include, for example, headphones (which have no earcups) or single sided headsets or headphones (i.e., which have a headband carrying a single earcup).

In the preferred headset 20 illustrated in FIG. 1, each of the earcups 170 having speakers 30 is attached to the headset 20 by a mounting bracket 180. It will be appreciated, therefore, that the phrase “mounting bracket,” as used herein, is meant to include both such stirrup-type brackets and any other mechanical connection of the earcup to the headset 20, including, for example, any structure which is integral to either the headset 20 or the earcup.

As can be seen from FIG. 1, the length of the headset 20 may be adjustable to accommodate heads of different sizes. Because this type of headset 20 may be relatively heavy, the headset 20 is designed to rest on the top of the user's head--adjustment of the length of the headset 20 therefore permits the user to properly position the earcups 170 with respect to the user's ears. Ear cushions 190 carried by the earcups 170 may be attached at the one or both ends of the headset 20 for engagement with the user's head either around or above the user's ear.

The electronic device holder assembly 70 is configured to releasably engage a portable electronic media device such as a MP3 player. That is, the electronic media device holder assembly 70 is capable of attaching to the portable electronic media device so that the portable electronic media device can be carried by the hands-free carrier 10 and supported by the head when the headset 20 is placed around the head. When attached, the electronic device holder assembly 70 securely mates with the portable electronic media device.

The electronic device holder assembly 70 can, for example, include a mechanical retention elements that utilizes such elements as, but not limited to, buttons, latches, snaps, hooks, tabs, flanges, lips, catches, detents and/or friction couplings for quickly and conveniently securing and releasing the portable electronic media device to the holder assembly 70.

It is contemplated that both the headset 20 and electronic device holder assembly 70 may be configured to carry signals to or from the portable electronic media device. For example, the holder assembly 70 may include a connector such as but not limited to, a media jack, video jack and/or a data connector that couples with corresponding connector on the portable electronic device. The connectors may be combined with the mechanical retention element and/or they may be separate components. It is contemplated that the signal carrying connection is made when the portable electronic media device is attached to the electronic device holder assembly 70.

The extension boom may be adjustable as in FIG. 4, or may be one continuous fixed piece as in FIG. 1. The extension boom 40 may be structurally attached to the holder assembly 70 via connection assembly 80.

Once the portable electronic media device is placed in the holder assembly 70, a variety of techniques may be used to mechanically retain the portable electronic media device to the holder assembly 70 including, but not limited to, friction, releasable clasps, detents, latches and/or catches. The mechanical retention element is secure yet not permanent so that the user can attach the portable electronic media device to the holder assembly 70 and have it remain attached while being worn or carried. However, the user can also conveniently detach the portable electronic media device from the holder assembly 70.

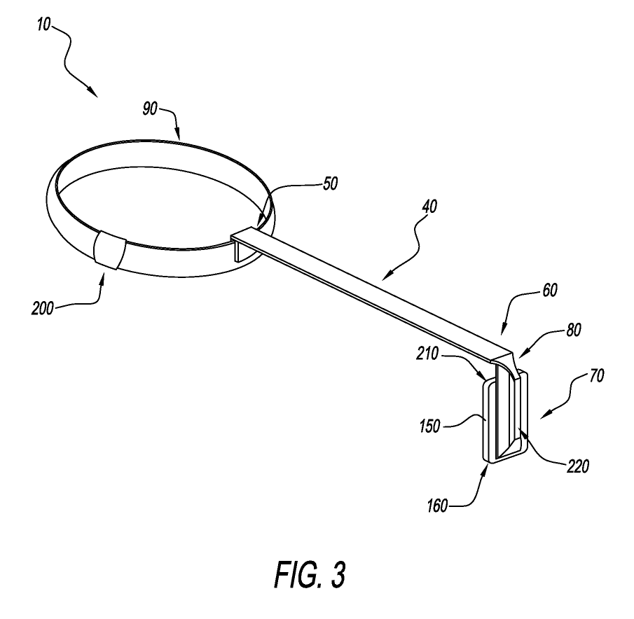

In one embodiment of the present invention, the headset is adjustable. As seen in FIGS. 1, 2, 4 and 6, the headset 20 is coupled together via an adjustable clasping system 200, for adjusting the size of the headset 20. The size of the headset 20 may be adjusted to fit around heads of various sizes and shapes. In one embodiment of the present invention, the headset is a headband. As seen in FIGS. 3, the headband 90 is coupled together via an adjustable clasping system 200, for adjusting the size of the headband 90. The size of the headband 90 may be adjusted to fit around heads of various sizes and shapes. In order to allow size adjustments, the clasps 200 of the headset 20 and headband 90 are configured to slidably adjust.

In one embodiment of the present invention, the headset includes a set of speakers. It is contemplated that the headset 20 may include inner wire conduit to allow media data in the form of electrical signals to be distributed from the portable electronic media device to the speakers 30. The inner wire conduits may, for example, be one or more conductive wires surrounded by a flexible insulation material such as plastic. The conduction of sound may be through a wireless or hard-wired system.

The proximal end 50 of extension boom 40 can be attached to the headset 20 via a connection assembly using a variety of techniques including but not limited to pivot hinges, stationary hinge, fusing, molding, epoxies, glues, clamps, teeth, clasps, etc. The same techniques can be used as the connection assembly 80 to attach the distal end 60 of extension boom 40 to the holder assembly 70. In one embodiment of the present invention, the extension boom is adjustable. In one embodiment of the present invention, the connection assembly is stationary. In one embodiment of the present invention, the connection assembly is rotatable. In one embodiment of the present invention, the connection assembly is a pivot hinge.

Holder assembly 70 is preferably made of a material that is tough, hard, and rigid, has good chemical resistance and dimensional stability is relatively strong, and is inexpensive. Accordingly, holder assembly 70 can be constructed of materials including but not limited to, acrylonitrile butadiene styrene (ABS), polycarbonate, polypropylene, polyethylene, or a similar material, all of which, to varying degrees, exhibit the stated properties. One or more of headset 20, headband 90, extension boom 40, earcups 170, holder assembly 70 and connection assembly 80 can be constructed of the same or similar materials.

The shapes, dimensions, materials of construction, arrangements of the parts, etc. of the various embodiments of this invention are not critical except as otherwise noted, and any shapes, dimensions, materials of construction, arrangements of the parts, etc. may be used provided they allow those embodiments to operate and one or more of the benefits of this invention to be achieved.

It is noted that the portable electronic media device does not have to be part of the present invention, although media devices could be sold and packaged with the present invention or sold separately.

Holder assembly 70 has a height sufficient to tightly hold the electronic media device. It will be understood by one skilled in the art that holder assembly 70 may be deeper (i.e., sidewall 150 and bottom wall 160) so as to provide more area to grip the electronic media device that is placed into the cavity. It will also be understood by one skilled in the art that holder assembly 70 may completely contain the electronic device, that is, the cavity may be formed by members that run along the sides of the device and are connected by a top member to completely encircle the electronic device. Holder assembly 70 may have any size and shape desired, consistent with the size and shape of the electronic device and the environment in which the present invention will be used to hold a portable electronic media device.

Although the cavity is desirably manufactured to provide as little distance as possible between the inner surface of the sidewall 150, bottom wall 160, top wall 210 and back wall 220 of the holder assembly 70 and the outer surface of the electronic device (so that the device will be firmly held in the cavity), as a practical matter, the cavity cannot be manufactured to provide a perfect fit under all conditions (e.g., with changes in ambient temperature) for several reasons, including variations in dimensions of both the cavity and the electronic device arising from manufacturing tolerances. Biasing members may be employed to help avoid this problem.

It is contemplated that holder assembly 70 includes biasing members (not shown) that help hold the electronic media device in position. Any type of one or more biasing members may be used, such as but not limited to, deformable plastic and/or elastic materials (e.g., elastomers and plastomers), spring-biased members (for example, leaf springs, ball-in-socket detents), and the like. The biasing members may be located at any one or more convenient locations in the cavity, for example, along the sidewall 150, bottom wall 160, top wall 210 and back wall 220 of the holder assembly 70. Biasing members help hold the device in position in the cavity by pushing against the device (even minimally), thereby forcing it towards another element that defines the cavity.

In one embodiment of the present invention, the holder assembly 70 has a length of approximately 1 to 20 inches (2.5 cm to 50 cm) and the extension boom 40 has a length of approximately of 4 to 20 inches (10 cm to 50 cm).

Connection assembly 80 may be hollow, thereby allowing electrical wires to be run through along the length of the extension boom 40, headset 20 to the speakers 30.

It is contemplated that the portable electronic media player may be coupled to holder assembly 70 via a dock connector (not shown). The term “couple,” “coupled,” “couples,” “coupling,” and the like should be broadly understood and refer to connecting two or more elements or signals, electrically and/or mechanically, either directly or indirectly through intervening circuitry and/or elements. The media player can be coupled to holder assembly 70 by any suitable means, such as but not limited to, the use of a serial port, a parallel port, a Universal Serial Bus (USB) port, or by an IEEE (Institute of Electrical and Electronic Engineers) connection.

The cavity of the holder assembly may be modified to contact and hold larger portions of the electronic media device so that it encircles most or all of the periphery of the portable electronic media player.

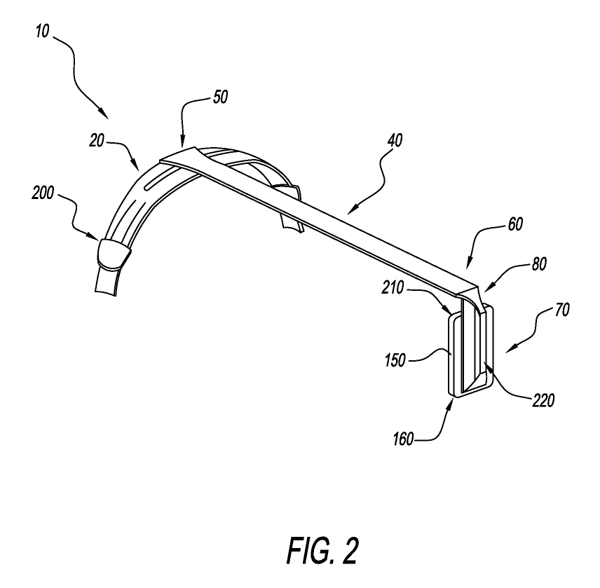

With respect to FIG. 2, an embodiment of the present invention is a hands-free carrier 10 for a portable electronic media player device having a headset 20, an extension boom 40 having a proximal end 50 and a distal end 60, the extension boom 40 being attached to the headset 20, the headset 20 being attached to the proximal end 50 of the extension boom 40; an holder assembly 70 suitable for holding a portable electronic media player device being attached to the distal end 60 of the extension boom 40 via a connection assembly. FIG. 2 also shows connection assembly 80, sidewalls 150, bottom wall 160, adjustable clasping system 200, top wall 210, and back wall 220.

With respect to FIG. 3, an embodiment of the present invention is a hands-free carrier 10 for a portable electronic media player device having a headband 90, an extension boom 40 having a proximal end 50 and a distal end 60, the extension boom 40 being attached to the headset 20, the headset 20 being attached to the proximal end 50 of the extension boom 40; an holder assembly 70 suitable for holding a portable electronic media player device being attached to the distal end of the extension boom 40 via a connection assembly. FIG. 3 also shows connection assembly 80, sidewalls 150, bottom wall 160, adjustable clasping system 200, top wall 210, and back wall 220.

With respect to FIG. 4, an embodiment of the present invention is a hands-free carrier 10 for a portable electronic media player device having a headset 20, the headset 20 having a set of speakers 30, an extension boom 40 that is adjustable, having a slidably adjustable mechanism 100, the extension boom having a proximal end 50 and a distal end 60, the extension boom 40 being attached to the headset 20, the headset 20 being attached to the proximal end 50 of the extension boom 40; an holder assembly 70 suitable for holding a portable electronic media player device being attached to the distal end 60 of the extension boom 40 via a pivotable connection assembly. FIG. 4 also shows pivot hinge 110, sidewalls 150, bottom wall 160, adjustable clasping system 200, and top wall 210.

The slidably adjustable mechanism 100 allows the user to adjust the distance between his eyes and the electronic device. The mechanism operates by allowing a thinner section of the extension boom 40 to slide into a hollow, larger section of the extension boom 40, such that a portion of the length of the thinner piece is now subsumed by the larger piece, and the overall length of the extension boom 40 is shorter. The length of the extension boom 40 can therefore be adjusted to a length desired by the user.

Variations and modifications of what has been described will be apparent to one skilled in the art. One or more parts of the hands-free carrier 10 may be detachable from the other parts. In another preferred embodiment, there is an additional strap, which may be adjustable by the user, which extends around the back of the head of the user, and is connected to head set 20, preferably each end of the strap is attached proximately to the each side of the adjustable clasping system 200.

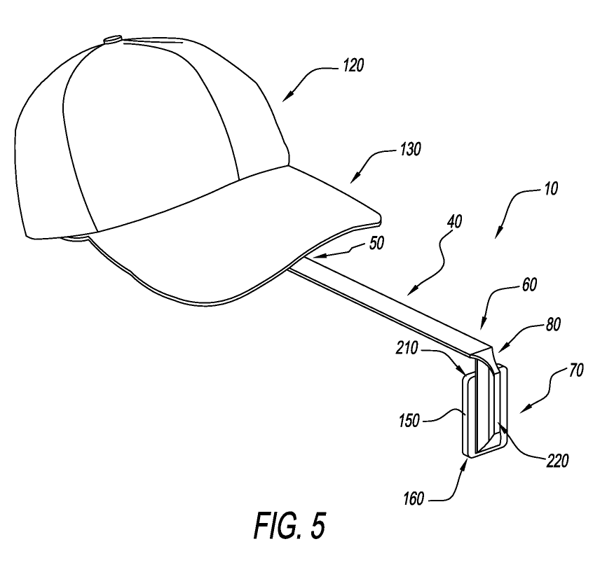

With respect to FIG. 5, an embodiment of the present invention is a hands-free carrier 10 for a portable electronic media player device constructed in the form of a cap having a visor, an extension boom 40 having a proximal end 50 and a distal end 60, the extension boom 40 being attached to the visor of the cap, an holder assembly 70 suitable for holding a portable electronic media player device being attached to the distal end of the extension boom 40 via a connection assembly. FIG. 5 also shows connection assembly 80, sidewalls 150, bottom wall 160, top wall 210, and back wall 220.

The construction of the above main elements of cap 120 is known in the art and will vary greatly with the quality and function of the cap. Usually, the cap 120 is made up of triangular fabric panels, usually six in number, sewn at the edges and intersecting at a common apex covered by a button. Two rear panels are cut out and join to make a cutout space to allow for adjustment via nylon or cloth straps with snap-in buttons or straps with Velcro® hook and loop fasteners, or a buckle assembly to adjust the circumference of the cap. A visor 130 may be sewn into the cap 120. The foregoing constitutes conventional cap construction and there are many variations that are applicable to the present invention.

Any type of hat or device that functions to cover part or all of the head and that is suitable may be worn and used with the hands-free carrier, including but not limited to, a cap, a fedora, a cowboy hat, a visor, a ladies' headband, etc. Alternately, the hands-free device may be partially covered with other headgear, for instance, a hat or scarf may be worn over the components of the hands-free device that contact the head.

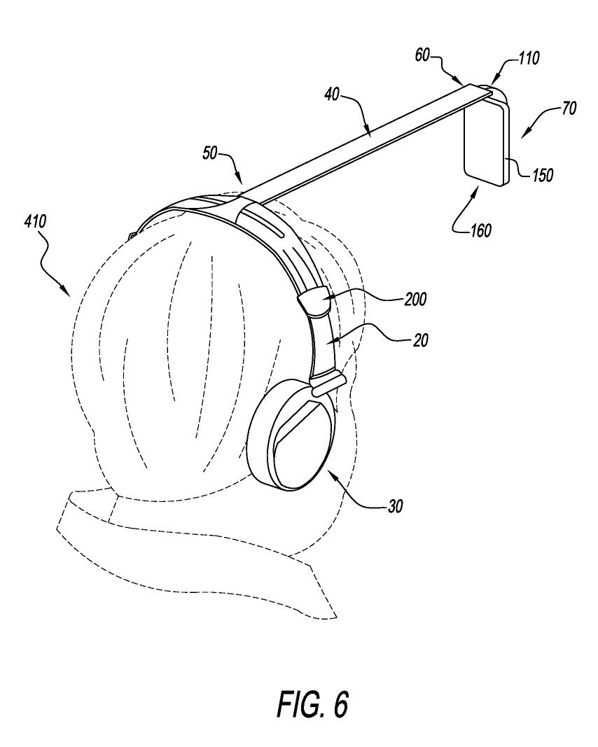

FIG. 6 is a perspective view from the back of a user wearing the hands-free carrier 10 depicted in FIG. 1.

The extension boom 40 between the headset 20 and holder assembly 70 is of sufficient length for the attached media device to be held in the field of vision of the user 410 when the headset 20 is in place and when the set of speakers are on the ears of the user. In this way the display of the media device can be seen and the control buttons and switches manipulated for the desired media content to be selected and heard at the desired volume.

FIG. 6 also shows set of speakers 30, extension boom proximal end 50, extension boom distal end 60, pivot hinge 110, sidewalls 150, bottom wall 160, and adjustable clasping system 200.

The advantages of the invention are numerous. Different aspects, embodiments or implementations may yield one or more of the following advantages.

One advantage of the invention is that portable electronic media devices can be conveniently worn, such as about one's head while remaining in the user's field of vision. This allows the user to easily manipulate the settings of the various parameters, such as items to download, volume, etc.

Another advantage is that, as shown in the embodiment shown in FIG. 4, the user can adjust the distance that the portable electronic device is from his eyes. Thus, the user can attain the most comfortable viewing parameters, and if he loans it to another user, they can adjust it to their own comfort level. This also allows the user to more easily store the hands-free carrier when not in use.

An additional advantage is that the pivot hinge described earlier allows the user another aspect of adjustment of the portable electronic device.

Although the invention has been described with reference to specific embodiments, it will be understood by those skilled in the art that various changes may be made without departing from the spirit or scope of the invention. Various examples of such changes have been given in the foregoing description. Accordingly, the disclosure of embodiments of the invention is intended to be illustrative of the scope of the invention and is not intended to be limiting. For example, to one of ordinary skill in the art, it will be readily apparent that the system discussed herein may be implemented in a variety of embodiments, and that the foregoing discussion of certain of these embodiments does not necessarily represent a complete description of all possible embodiments. Rather, the detailed description of the drawings, and the drawings themselves, disclose at least one preferred embodiment of the invention, and may disclose alternative embodiments of the invention.

What is claimed is:

1. A hands-free carrier for a portable electronic media player device, said carrier comprising:
a headset;
an extension boom having a proximal end and a distal end;
the extension boom being attached to the headset;
the headset being attached to the proximal end of the extension boom; and
an holder assembly suitable for holding a portable electronic media player device being attached to the distal end of the extension boom via a connection assembly.

2. The hands-free carrier of claim 1, wherein the headset is adjustable.

3. The hands-free carrier of claim 1, wherein the headset includes a set of speakers.

4. The hands-free carrier of claim 1, wherein the extension boom is adjustable.

5. The hands-free carrier of claim 1, wherein the connection assembly is stationary.

6. The hands-free carrier of claim 1, wherein the connection assembly is rotatable.

7. The hands-free carrier of claim 1, wherein the connection assembly is a pivot hinge.

8. The hands-free carrier of claim 1, wherein the headset is a headband.

9. A hands-free carrier for a portable electronic media player device, said holder comprising:
a cap;
an extension boom having a proximal and a distal end;
the cap being attached to the proximal end of the extension boom; and
an assembly suitable for holding a portable electronic media player device being attached to the distal end of the extension boom via a connection assembly.

10. The hands-free carrier of claim 9, wherein the cap has a visor and the proximal end of the extension boom is attached to the visor.

11. The hands-free carrier of claim 9, wherein the extension boom is adjustable.

12. The hands-free carrier of claim 9, wherein the connection assembly is stationary.

13. The hands-free carrier of claim 9, wherein the connection assembly is rotatable.

14. The hands-free carrier of claim 9, wherein the connection assembly is a pivot hinge.

15. A hands-free carrier for a portable electronic media player device, said carrier comprising:
a head band for encircling the head of a user;
an extension boom having a proximal end and a distal end;
the extension boom being attached to the head band;
the head band being attached to the proximal end of the extension boom; and
an holder assembly suitable for holding a portable electronic media player device being attached to the distal end of the extension boom via a connection assembly.

16. The hands-free carrier of claim 15, wherein the extension boom is adjustable.

17. The hands-free carrier of claim 15, wherein the connection assembly is stationary.

18. The hands-free carrier of claim 15, wherein the connection assembly is rotatable.

19. The hands-free carrier of claim 15, wherein the connection assembly is a pivot hinge.
